(19) United States
(12) Patent Application Publication
(10) Pub. No.: US 2002/0061640 A1
(43) Pub. Date: May 23, 2002

(54) Method of manufacturing passivation layer

(75) Inventor: Mu-Chun Wang, Hsinchu Hsien (TW)

Correspondence Address: J. C. PATENTS, 4 Venture, Suite 250, Irvine, CA, 92618, US

(73) Assignee: United Microelectronics Corp., No. 3, Hsinchu (TW)

(21) Appl. No.: 09/734,840

(22) Filed: Dec. 11, 2000

(30) Foreign Application Priority Data
Nov. 22, 2000 (TW) 89124752

(51) Int. Cl. H01L 21/44; H01L 21/31; H01L 21/469

(52) U.S. Cl. 438/612; 438/787; 438/791; 438/613

(57) ABSTRACT

A method of manufacturing a passivation layer. A substrate having semiconductor devices thereon is provided. A dielectric layer is next formed over the substrate. A liner layer is formed over the dielectric layer. A bonding pad for electrically connecting the semiconductor device in the substrate with an external package frame is formed over the liner layer. A passivation layer is formed over the substrate to protect the circuits and devices thereon. A portion of the passivation layer is removed to expose a portion of the bonding pad. Wire-bonding operation is finally carried out to put wires on the bonding pad.

### CROSS-REFERENCE TO RELATED APPLICATION

This application claims the priority benefit of Taiwan application Ser. no. 89124752, filed Nov. 22, 2000.

### BACKGROUND OF THE INVENTION

1. Field of Invention

The present invention relates to a method of manufacturing a passivation layer. More particularly, the present invention relates to a method of increasing the hardness of a passivation layer.

2. Description of Related Art

In the process of fabricating semiconductor devices, neighboring conductive structures are often isolated from each other by a dielectric insulation layer. Examples of the conductive structures include interconnects, gate electrode and via plugs. As feature line width of semiconductors continues to decrease, distance of separation between neighboring conductive lines is correspondingly reduced. Common dielectric insulating materials including hydrogen silsesquioxane (HSQ) and methyl silsesquioxane (or MSQ has a dielectric constant of between 2.6 to 2.8) have low dielectric constant.

However, these low dielectric constant materials are often porous and soft. Hence, the dielectric insulating material can hardly provide sufficient strength to support the subsequently formed conductive wires so that adhesion between the conductive wire and bonding pads is poor. In addition, the porosity of the dielectric layer often leads to the infiltration of moisture and results in dielectric constant instability. Ultimately, current leak may occur and device reliability may be compromised.

### SUMMARY OF THE INVENTION

Accordingly, one object of the present invention is to provide method of manufacturing a passivation layer. The method includes forming a liner layer over a dielectric layer to serve as a passivation layer. Hence, adhesion between a conductive wire and a bonding pad in a subsequent wire-bonding operation is improved and infiltration of moisture into the dielectric layer is prevented. With an increase in the stability of the dielectric layer, current leakage is minimized and reliability of product is raised.

To achieve these and other advantages and in accordance with the purpose of the invention, as embodied and broadly described herein, the invention provides a method of manufacturing a passivation layer. First, a substrate having semiconductor devices thereon is provided. A dielectric layer is next formed over the substrate. A liner layer is formed over the dielectric layer. A bonding pad for electrically connecting the semiconductor device in the substrate with an external package frame is formed over the liner layer. A passivation layer is formed over the substrate to protect the circuits and devices thereon. A portion of the passivation layer is removed to expose a portion of the bonding pad. Wire-bonding operation is next carried out to put wires on the bonding pad.

In the aforementioned steps, the liner layer is formed using a material such as fluorosilicate glass (FSG) or silicon nitride. Furthermore, the liner layer has a multi-layered stack structure. The dielectric layer is formed using a low dielectric constant material such as silsesquioxane.

In this invention, a liner layer is formed over the dielectric layer before forming the passivation layer. The liner layer has a greater hardness and can provide the strength needed to support subsequent wire-bonding operation. Hence, the conductive wires and the bonding pad can have better adhesion. In addition, since the dielectric layer is formed using a low dielectric constant material of high porosity, moisture can easily be absorbed by the dielectric layer if exposed. By forming a hard liner layer, moisture is prevented from getting into the dielectric layer. The dielectric constant of the dielectric layer will remain relatively stable and current leakage problem will be minimized.

It is to be understood that both the foregoing general description and the following detailed description are exemplary, and are intended to provide further explanation of the invention as claimed.

### BRIEF DESCRIPTION OF THE DRAWING

The accompanying drawing is included to provide a further understanding of the invention, and is incorporated in and constitutes a part of this specification. The drawing illustrates embodiment of the invention and, together with the description, serves to explain the principles of the invention. In the drawing,

FIG. 1 is a schematic cross-sectional side view showing the steps for producing a passivation layer according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

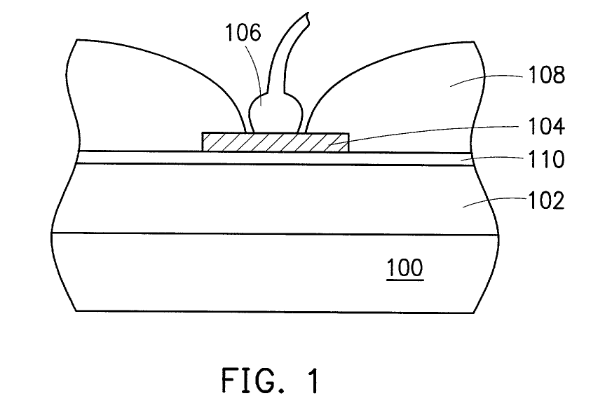

FIG. 1 is a schematic cross-sectional side view showing the steps for producing a passivation layer according to one preferred embodiment of this invention.

As shown in FIG. 1, a substrate 100 having a plurality of semiconductor devices (not shown) thereon is provided. A dielectric layer 102 is formed over the substrate 100. The dielectric layer 102 can be formed, for example, by chemical vapor deposition. In general, the dielectric layer 102 is formed using a low dielectric constant material such as silsesquioxane, preferably hydrogen silsesquioxane (HSQ) or methyl silsesquioxane (MSQ).

A liner layer 110 is formed over the dielectric layer 102. The liner layer 110 can have a multiple-layered stack structure formed by depositing fluorosilicate glass or silicon nitride in a chemical vapor deposition. Preferably, the liner layer 110 is made using fluorosilicate glass or a material with great hardness. The ratio between the thickness of the dielectric layer 102 and the liner layer 110 varies according to the required dielectric constant value. For a dielectric layer with a constant dielectric constant, the ratio between the thickness of the dielectric layer 102 and the liner layer 110 is preferably about 10:1.

Because the liner layer 110 is relatively hard, the liner layer 110 can provide a stiff support necessary for performing a subsequent wire-bonding operation. Hence, the adhesion between a conductive wire and a bonding pad is increased. With a thickness ratio between the dielectric layer 102 and the liner layer 110 of about 10:1, dielectric constant of the dielectric layer 102 is maintained despite the hardening of the dielectric layer 102 by the liner layer 110. Furthermore, the liner layer 110 can serve as a protective layer preventing moisture from entering the porous dielectric layer 102. Hence, dielectric constant instability is suppressed and current leakage problem is minimized.

The liner layer 110 between the dielectric layer 102 and a bonding pad 104 also confers some flexibility to the dielectric layer 102. Thus, the substrate chip is less vulnerable to breakage during wire-bonding operation.

After forming the liner layer 110 over the dielectric layer 102, a bonding pad 104 is formed over the liner layer 110. The bonding pad can be formed, for example, by depositing a conductive material in a chemical vapor deposition and then patterning the conductive layer. The bonding pad 104 electrically connects the semiconductor device in the substrate 100 with an external package structure.

A passivation layer 108 is formed over the semiconductor substrate 100. The passivation layer 108 is formed, for example, by chemical vapor deposition. Material constituting the passivation layer can be silicon nitride or phosphosilicate glass (PSG), for example. The passivation layer 108 serves as a barrier preventing the penetration of moisture and alkali ions so that the devices on the substrate 100 is protected against mechanical damages.

A portion of the passivation layer 108 is removed to expose a portion of the bonding pad 104. Thereafter, a wire-bonding operation is carried out to bond one end of a conductive wire 106 onto the bonding pad surface. The conductive wire includes gold wire, for example.

Because the liner layer 110 can stiffen the underlying dielectric layer 102, wire-bonding strength between the conductive wire 106 and the bonding pad 104 will improve.

In summary, a hard liner layer is formed over a dielectric layer in this invention so that the adhesion between a subsequently bonded conductive wire and a bonding pad on the liner layer is increased. Moreover, the liner layer is able to prevent the infiltration of moisture into the intrinsically porous dielectric layer. Ultimately, dielectric constant of the dielectric layer will remain stable and current leakage problem will disappear.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of manufacturing a passivation layer, comprising the steps of:
providing a substrate having a dielectric layer thereon;
forming a liner layer over the dielectric layer;
forming a bonding pad over the liner layer;
forming a passivation layer over the substrate;
patterning the passivation layer to expose a portion of the bonding pad; and
performing a wire-bonding operation.

2. The method of claim 1, wherein the liner layer includes a fluorosilicate glass layer.

3. The method of claim 1, wherein the liner layer includes a silicon nitride layer.

4. The method of claim 1, wherein the ratio between the thickness of the dielectric layer and the liner layer is about 10:1.

5. The method of claim 1, wherein the liner layer includes a multiple-layered stack structure.

6. The method of claim 1, wherein the step of forming the liner layer includes chemical vapor deposition.

7. The method of claim 1, wherein the step of forming a passivation layer over the substrate includes depositing phosphosilicate glass or silicon nitride.

8. The method of claim 1, wherein the wire-bonding operation is carried out using gold wires.

9. The method of claim 1, wherein the step of forming the bonding pad over the liner layer includes the sub-steps of:
forming a conductive layer over the liner layer; and
patterning the conductive layer the bonding pad.

10. A method of manufacturing a passivation layer over a semiconductor substrate having a silsesquioxane layer thereon, comprising the steps of:
forming a fluorosilicate glass layer over the silsesquioxane layer;
forming a bonding pad over the fluorosilicate glass layer;
forming a passivation layer over the semiconductor substrate;
patterning the passivation layer to expose a portion of the bonding pad; and
performing a wire-bonding operation.

11. The method of claim 10, wherein the ratio of the thickness between the silsesquioxane layer and the fluorosilicate glass layer is about 10:1

12. The method of claim 10, wherein the fluorosilicate glass layer includes a multiple-layered stack structure.

13. The method of claim 10, wherein the step of forming the fluorosilicate glass layer includes chemical vapor deposition.

14. The method of claim 10, wherein the step of forming the passivation layer includes depositing phosphosilicate glass or silicon nitride.

15. The method of claim 10, wherein the wire-bonding operation is carried out using gold wires.

16. The method of claim 10, wherein the step of forming the bonding pad over the fluorosilicate glass layer includes the sub-steps of:
forming a conductive layer over the fluorosilicate glass layer; and
patterning the conductive layer the bonding pad.
